(19) United States
(12) Patent Application Publication
(10) Pub. No.: US 2025/0081426 A1
(43) Pub. Date: Mar. 6, 2025

(54) SEMICONDUCTOR DEVICE AND METHOD FOR FABRICATING THE SAME

(71) Applicant: SK hynix Inc., Gyeonggi-do (KR)

(72) Inventor: Wha Young KIM, Gyeonggi-do (KR)

(21) Appl. No.: 18/409,813

(22) Filed: Jan. 11, 2024

(30) Foreign Application Priority Data
Aug. 31, 2023 (KR) 10-2023-0115279

(51) Int. Cl. H10B 12/00

(52) U.S. Cl. CPC H10B 12/315; H10B 12/482; H10B 12/488; H10B 12/03; H10B 12/05

(57) ABSTRACT

A semiconductor device and a method for fabricating the same are provided. The semiconductor device includes a substrate; a lower portion of a first conductive pattern disposed over the substrate and extending in a second direction; a stacked structure disposed over the lower portion of the first conductive pattern and having a pillar shape, the stacked structure including an upper portion of the first conductive pattern, an oxide semiconductor channel, and a second conductive pattern; and a word line extending in a first direction intersecting the second direction and facing at least a portion of a sidewall of the oxide semiconductor channel with a gate insulating layer therebetween, wherein the first conductive pattern includes a first conductive metal oxide, and the lower portion of the first conductive pattern corresponds to a bit line, and the upper portion of the first conductive pattern corresponds to a drain electrode.

### CROSS-REFERENCE TO RELATED APPLICATION

This application claims priority under 35 U.S.C. § 119 to Korean Patent Application No. 10-2023-0115279 filed on Aug. 31, 2023, which is incorporated herein by reference in its entirety.

### BACKGROUND

### 1. Technical Field

Embodiments of the present disclosure relate to a semiconductor technology, and particularly, to a semiconductor device including a transistor and a method for fabricating the same.

### 2. Related Art

With the development of the electronics industry, electronic products are becoming increasingly smaller, higher-performance, and more highly integrated, while the operating speed of the electronic products is required to increase.

To meet these demands, there is a need to develop technologies that can maintain and/or improve the characteristics of unit elements that make up electronic products, such as transistors, while reducing their size.

### SUMMARY

In an embodiment of the present disclosure, a semiconductor device may include: a substrate; a lower portion of a first conductive pattern disposed over the substrate and extending in a second direction; a stacked structure disposed over the lower portion of the first conductive pattern and having a pillar shape, the stacked structure including an upper portion of the first conductive pattern, an oxide semiconductor channel, and a second conductive pattern; and a word line extending in a first direction intersecting the second direction and facing at least a portion of a sidewall of the oxide semiconductor channel with a gate insulating layer therebetween, wherein the first conductive pattern includes a first conductive metal oxide, and the lower portion of the first conductive pattern corresponds to a bit line, and the upper portion of the first conductive pattern corresponds to a drain electrode.

In another embodiment of the present disclosure, a semiconductor device may include: a substrate; a bit line disposed over the substrate and extending in a second direction; a stacked structure disposed over the bit line and having a pillar shape, the stacked structure including a drain electrode, an oxide semiconductor channel, and a conductive pattern; and a word line extending in a first direction intersecting the second direction and facing at least a portion of a sidewall of the oxide semiconductor channel with a gate insulating layer therebetween, wherein the conductive pattern includes a conductive metal oxide, and a lower portion of the conductive pattern corresponds to a source electrode, and an upper portion of the conductive pattern corresponds to a lower electrode of a capacitor.

In another embodiment of the present disclosure, a method for fabricating a semiconductor device, may include: forming a first conductive layer, an oxide semiconductor layer, and a second conductive layer, over a substrate; patterning an upper portion of the first conductive layer, the oxide semiconductor layer, and the second conductive layer to form a stacked structure including an upper first conductive pattern, an oxide semiconductor channel, and a second conductive pattern and having a pillar shape; patterning a lower portion of the first conductive layer to form a lower first conductive pattern having a line shape extending in a second direction; and forming a word line extending in a first direction intersecting the second direction and facing at least a portion of a sidewall of the oxide semiconductor channel with a gate insulating layer therebetween, wherein the first conductive layer includes a first conductive metal oxide, and the lower first conductive pattern corresponds to a bit line, and the upper first conductive pattern corresponds to a drain electrode.

In another embodiment, a method for fabricating a semiconductor device, may include: forming a bit line extending in a second direction over a substrate; forming a stacked structure including a drain electrode, an oxide semiconductor channel, and a conductive pattern including a conductive metal oxide and having a pillar shape, over the bit line; forming a word line extending in a first direction intersecting the second direction and facing at least a portion of a sidewall of the oxide semiconductor channel with a gate insulating layer therebetween; forming an insulating pattern that covers the word line and protrudes an upper portion of the conductive pattern; and forming an upper electrode of a capacitor facing the upper portion of the conductive pattern with the gate insulating layer or a capacitor insulating layer therebetween, wherein the upper portion of the conductive pattern corresponds to a lower electrode of the capacitor, and a lower portion of the conductive pattern, excluding the upper portion of the conductive pattern, corresponds to a source electrode.

In another embodiment of the present disclosure, a semiconductor device may include: a substrate; a first conductive pattern disposed over the substrate and extending in a second direction, the first conductive pattern consisting of a line shape bottom part covering a top surface of the substrate, and a plurality of spaced apart pillar shape top parts rising over the bottom part in a vertical direction; a plurality of stacked structures, each stacked structure disposed over a corresponding one of the pilar shape top parts of the first conductive pattern and having a pillar shape, each stacked structure including an oxide semiconductor channel, and a second conductive pattern sequentially stacked; and a word line extending in a first direction intersecting the second direction and facing at least a portion of a sidewall of the oxide semiconductor channel with a gate insulating layer therebetween.

These and other features and advantages of the present invention will become better understood from the detailed description of specific example embodiments in conjunction with the following figures.

### BRIEF DESCRIPTION OF THE DRAWINGS

FIGS. 1A to 11 are simplified schematics illustrating a semiconductor device according to an embodiment of the present disclosure, and a method for fabricating the same.

FIGS. 12 and 13 are simplified cross-sectional view schematics illustrating a semiconductor device according to another embodiment of the present disclosure, and a method for fabricating the same.

FIGS. 14 and 15 are simplified cross-sectional view schematics illustrating a semiconductor device according to another embodiment of the present disclosure, and a method for fabricating the same.

FIG. 16 is a simplified cross-sectional view schematic illustrating a semiconductor device according to another embodiment of the present disclosure, and a method for fabricating the same.

### DETAILED DESCRIPTION

Hereinafter, various embodiments of the present disclosure will be described in detail with reference to the accompanying drawings.

The drawings are not necessarily drawn to scale. In some instances, proportions of at least some structures in the drawings may have been exaggerated to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

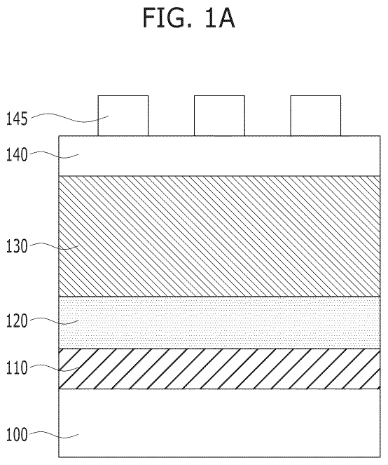

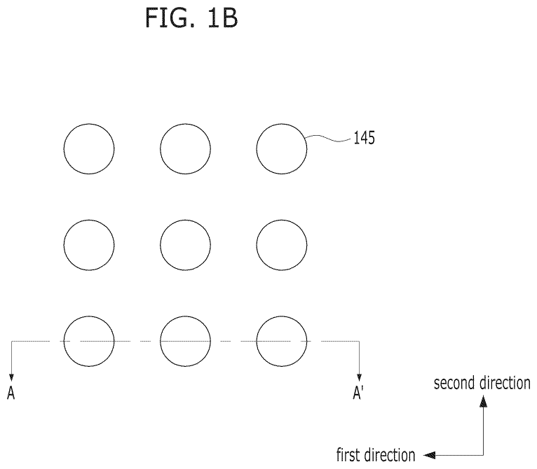

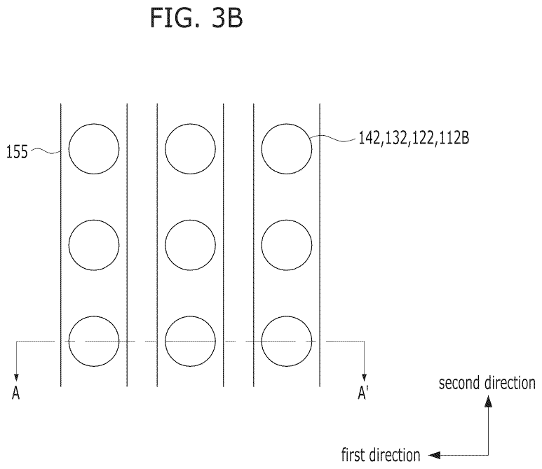

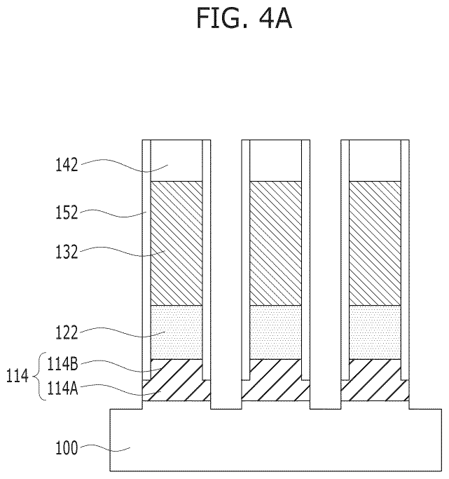

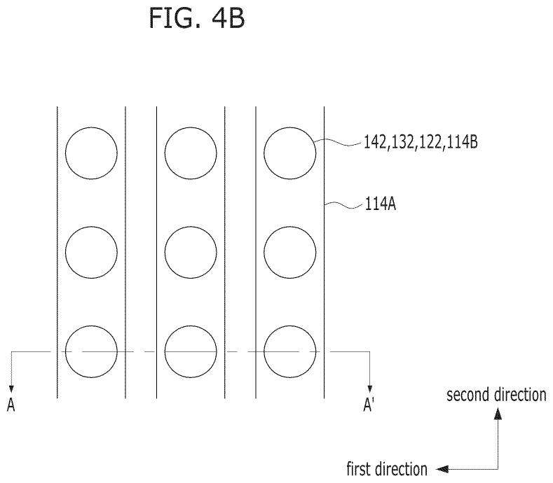

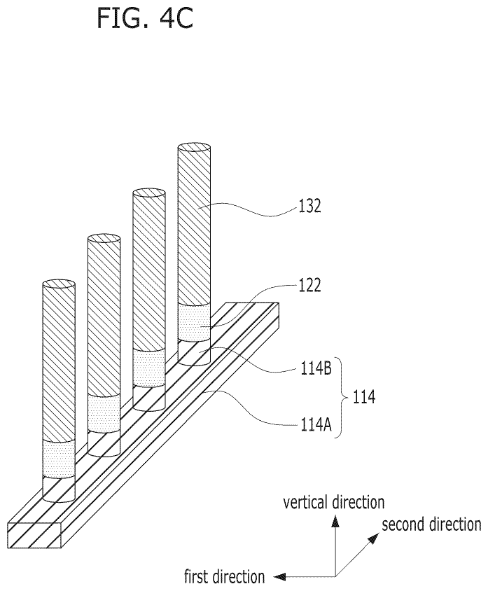

FIGS. 1A to 11 are simplified schematics illustrating a semiconductor device according to an embodiment of the present disclosure, and a method for fabricating the same. FIGS. 1A, 2A, 3A, 4A, 5, 6, 7, 8A, 9A, 10, and 11 are simplified cross-sectional view schematics, and FIGS. 1B, 2B, 3B, 4B, 8B, and 9B are simplified plan view schematics respectively corresponding to FIGS. 1A, 2A, 3A, 4A, 8A, and 9A. Cross sections along lines A-A′ in FIGS. 1B, 2B, 3B, 4B, 8B, and 9B may correspond to FIGS. 1A, 2A, 3A, 4A, 8A, and 9A, respectively. FIG. 4C is a simplified perspective view schematic showing a portion of FIGS. 4A and 4B.

First, the fabricating method of the semiconductor device of an embodiment of the present disclosure is described.

Referring to FIGS. 1A and 1B, a first conductive layer 110, an oxide semiconductor layer 120, a second conductive layer 130, a first hard mask layer 140, and a first mask pattern 145 may be formed over a substrate 100. The first conductive layer 110, the oxide semiconductor layer 120, the second conductive layer 130, the first hard mask layer 140, and the first mask pattern 145 may be formed sequentially over the substrate 100 in the recited order. The first conductive layer 110, the oxide semiconductor layer 120, the second conductive layer 130, and the first hard mask layer 140 may have a plate shape to cover the substrate 100. In the plan view schematic of FIG. 1B, only the first mask pattern 145 is shown. In the plan view schematic of FIG. 1B and also in other simplified plan view schematics to be described later, components that are not patterned may be omitted for convenience of description.

The substrate 100 may include a semiconductor material such as silicon and may include required substructures (not shown). As an example, the substrate 100 may include a peripheral circuit, an insulating layer covering the peripheral circuit, etc.

The first conductive layer 110 may function as a bit line and a drain electrode by a patterning process to be described later and may include at least one of various conductive materials. In particular, in the present embodiment, the first conductive layer 110 may include a conductive metal oxide, such as indium tin oxide (ITO), indium oxide (In₂O₃), or a metallic oxide semiconductor. The metallic oxide semiconductor may refer to a material that has a higher metal content than a typical oxide semiconductor and has a lower resistance than the typical oxide semiconductor, thereby having conductivity. For example, the metallic oxide semiconductor may include indium-rich indium gallium zinc oxide (IGZO). Indium-rich IGZO may refer to a material in which an indium content is higher than a gallium content and higher than a zinc content, for example, a material with an indium content of 40% or more.

The oxide semiconductor layer 120 may be a part that functions as a channel of a transistor by a patterning process described later. The oxide semiconductor layer 120 may include at least one of various oxide semiconductors such as indium gallium zinc oxide (IGZO), indium zinc tin oxide (IZTO), zinc tin oxide (ZTO), indium gallium oxide (IGO), InO₂, or the like.

The second conductive layer 130 may function as a lower electrode of the capacitor and a source electrode by a patterning process described later and may include at least one of various conductive materials. In the present embodiment, the second conductive layer 130 may include a conductive metal oxide such as ITO, In₂O₃, or a metallic oxide semiconductor. The second conductive layer 130 may be formed of the same material or a different material from the first conductive layer 110.

The first hard mask layer 140 may be a part that functions as an etch barrier when etching a portion of the first conductive layer 110, the oxide semiconductor layer 120, and the second conductive layer 130, and may include at least one of various materials such as silicon oxide, silicon nitride, polysilicon, carbon, or a combination thereof.

Each of the first conductive layer 110, the oxide semiconductor layer 120, the second conductive layer 130, and the first hard mask layer 140 may be formed using at least one of various deposition methods.

The first mask pattern 145 may include a photoresist, and may have an island shape. In the present embodiment, the first mask pattern 145 is shown as having a circular shape in a plan view. However, the present disclosure is not limited thereto, and the first mask pattern 145 may have at least one of various shapes, such as an elliptical shape, a rectangular shape, or a square shape in a plan view. A plurality of first mask patterns 145 may be arranged in a spaced apart relationship to each other in a matrix form along first and second directions. For reference, the first direction and the second direction may be substantially parallel to the surface, such as the upper surface, of the substrate 100, and may intersect each other. The first direction and the second direction may be orthogonal to each other.

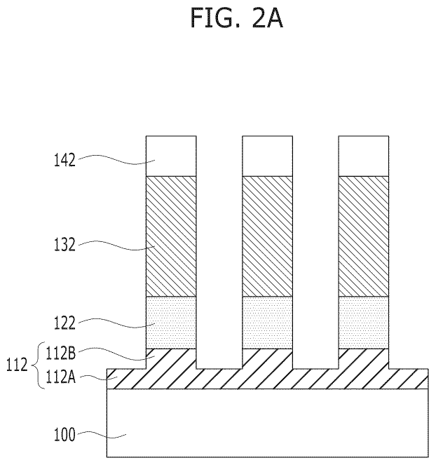

Referring to FIGS. 2A and 2B, the first hard mask layer 140, the second conductive layer 130, the oxide semiconductor layer 120, and a portion of the first conductive layer 110 may be etched using the first mask pattern 145 as an etch barrier to form a first hard mask pattern 142, a second conductive pattern 132, an oxide semiconductor pattern 122, and an initial first conductive pattern 112. During this etching process, the first mask pattern 145 may be removed. Alternatively, the first mask pattern 145 may be removed through a separate removal process, such as an oxygen stripping process.

The initial first conductive pattern 112 may include an etched upper portion 112B and an unetched lower portion 112A. A stacked structure of the upper portion 112B of the initial first conductive pattern 112, the oxide semiconductor pattern 122, the second conductive pattern 132, and the first hard mask pattern 142 may have a pillar shape, and a plurality of stacked structures may be arranged in a matrix form along the first and second directions. In the present embodiment, the pillar-shaped stacked structure is shown as having a circular shape in a plan view. However, the present disclosure is not limited thereto, and the stacked structure may have at least one of various shapes, such as an elliptical shape, a rectangular shape, or a square shape in a plan view. The lower portion 112A of the initial first conductive pattern 112 may maintain a flat plate shape. The upper portion 112B of the initial first conductive pattern 112 may correspond to a drain electrode, the oxide semiconductor pattern 122 may correspond to a channel of a transistor, a lower portion of the second conductive pattern 132 may correspond to a source electrode, and an upper portion of the second conductive pattern 132 may correspond to a lower electrode of a capacitor. Since the lower and upper portions of the second conductive pattern 132 are defined through a subsequent process, they will be described in more detail in the corresponding section.

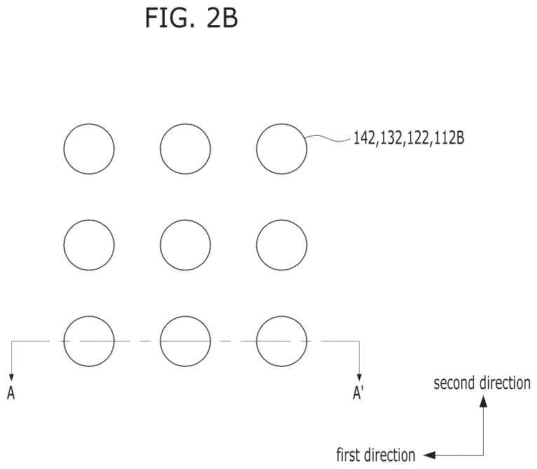

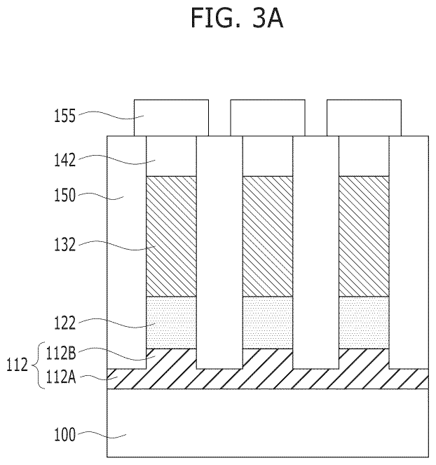

Referring to FIGS. 3A and 3B, a first insulating layer 150 may be formed to fill the space between the stacked structures of the upper portion 112B of the initial first conductive pattern 112, the oxide semiconductor pattern 122, the second conductive pattern 132, and the first hard mask pattern 142.

The first insulating layer 150 may include silicon oxide, silicon nitride, silicon oxynitride, or a combination thereof. The first insulating layer 150 may be formed by depositing an insulating material that covers the process result of FIGS. 2A and 2B, and performing a planarization process, such as a CMP (Chemical Mechanical Polishing) process, so that the top surface of the first hard mask pattern 142 is exposed.

Subsequently, a second mask pattern 155 may be formed over the first hard mask pattern 142 and the first insulating layer 150. Although not shown, before forming the second mask pattern 155, an additional hard mask material may be further formed over the first hard mask pattern 142 and the first insulating layer 150.

The second mask pattern 155 may include photoresist and may have a line shape extending in the second direction, thereby covering the stacked structures of the upper portion 112B of the initial first conductive pattern 112, the oxide semiconductor pattern 122, the second conductive pattern 132, and the first hard mask pattern 142, that are arranged in the second direction. To sufficiently cover the stacked structure in the first direction, the width of the second mask pattern 155 in the first direction may be greater than the width of the stacked structure in the first direction.

Referring to FIGS. 4A to 4C, the first insulating layer 150 and the lower portion 112A of the initial first conductive pattern 112 may be etched using the second mask pattern 155 as an etch barrier to form an initial first insulating pattern 152 and a first conductive pattern 114. During this etching process, the second mask pattern 155 may be removed. Alternatively, the second mask pattern 155 may be removed through a separate removal process, such as an oxygen stripping process. During this etching process, a portion of the substrate 100 may be caved in due to excessive etching.

The upper portion 114B of the first conductive pattern 114 may be maintained in the same pillar shape as the upper portion 112B of the initial first conductive pattern 112 described above. On the other hand, since the lower portion 114A of the first conductive pattern 114 is formed using the second mask pattern 155, it may have a line shape extending in the second direction. The lower portion 114A of the first conductive pattern 114 may correspond to a bit line. The width of the lower portion 114A of the first conductive pattern 114 in the first direction may be greater than the width of the stacked structure of the upper portion 114B of the first conductive pattern 114, the oxide semiconductor pattern 122, the second conductive pattern 132, and the first hard mask pattern 142 in the first direction.

The insulating pattern 152 may cover the sidewall of the stacked structure of the upper portion 114B of the first conductive pattern 114, the oxide semiconductor pattern 122, the second conductive pattern 132, and the first hard mask pattern 142, and may be disposed over the lower portion 114A of the first conductive pattern 114 to expose the sidewall of the lower portion 114A of the first conductive pattern 114.

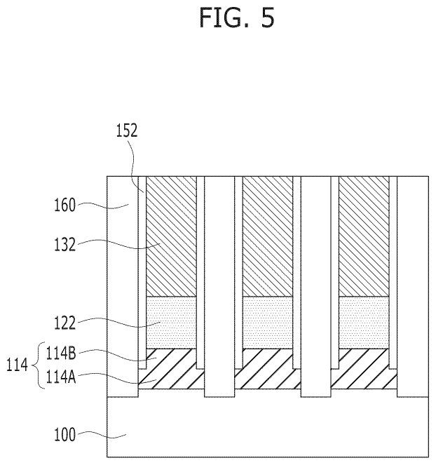

Referring to FIG. 5, a second insulating layer 160 may be formed to fill the space between the lower portions 114A of the first conductive patterns 114 and also between the initial first insulating patterns 152.

The second insulating layer 160 may include silicon oxide, silicon nitride, silicon oxynitride, or a combination thereof. The second insulating layer 160 may be formed by depositing an insulating material covering the process result of FIGS. 4A and 4B, and performing a planarization process, such as a CMP process, so that the top surface of the second conductive pattern 132 is exposed.

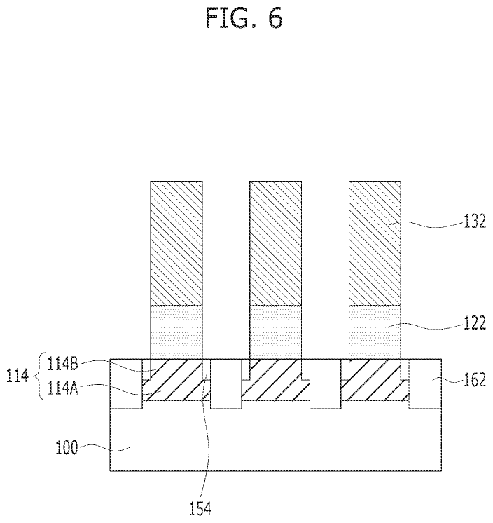

Referring to FIG. 6, the initial first insulating pattern 152 and the second insulating layer 160 may be recessed to expose the sidewall of the oxide semiconductor pattern 122, thereby forming a first insulating pattern 154 and a second insulating pattern 162.

The recess process may be performed by a dry or wet etching method using a gas or a chemical that can selectively remove only an insulating material. When the initial first insulating pattern 152 and the second insulating layer 160 are formed of the same material, they may be recessed at once using the same etching gas or chemical. The upper surfaces of the first second insulating patterns 154 and 162 formed through this recess process may be located at substantially the same height from the surface of the substrate 100.

In the present embodiment, the recess process may be performed so that the entire sidewall of the oxide semiconductor pattern 122 is exposed. That is, the top surface of the first insulating pattern 154 and the top surface of the second insulating pattern 162 may be positioned at substantially the same height as the bottom surface of the oxide semiconductor pattern 122. However, the present disclosure is not limited thereto, and the recess process may be performed so that a portion of the sidewall of the oxide semiconductor pattern 122 is exposed. In this case, the top surface of the first insulating pattern 154 and the top surface of the second insulating pattern 162 may be located at a height between the bottom surface and the top surface of the oxide semiconductor pattern 122. In this recess process, the second conductive pattern 132 which extends over the oxide semiconductor pattern 122 may be exposed.

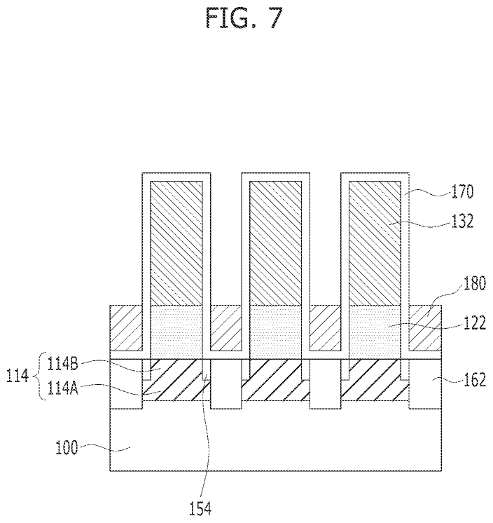

Referring to FIG. 7, a gate insulating layer 170 may be formed conformally along its lower profile over the process result of FIG. 6. Accordingly, the gate insulating layer 170 may be formed to cover the sidewall and the top surface of the stacked structure of the oxide semiconductor pattern 122 and the second conductive pattern 132, and the upper surfaces of the first and second insulating patterns 154 and 162.

The gate insulating layer 170 may be formed by at least one of various deposition methods and may include at least one of various insulating materials such as silicon oxide, silicon nitride, silicon oxynitride, or a high dielectric constant material with a higher dielectric constant than silicon oxide.

Subsequently, a third conductive layer 180 may be formed over the gate insulating layer 170 to a thickness that fills the space between the oxide semiconductor patterns 122.

In the present embodiment, the third conductive layer 180 may be formed to a thickness that completely fills the space between the oxide semiconductor patterns 122. That is, the height of the top surface of the third conductive layer 180 may be substantially the same as the height of the top surface of the oxide semiconductor pattern 122. However, the present disclosure is not limited thereto, and the height of the top surface of the third conductive layer 180 may be modified in various ways as long as it is less than or equal to the height of the top surface of the oxide semiconductor pattern 122. For example, the top surface of the third conductive layer 180 may be located at a height between the top and bottom surfaces of the oxide semiconductor pattern 122, and accordingly, the third conductive layer 180 may partially fill the space between the oxide semiconductor patterns 122.

The third conductive layer 180 may include at least one of various conductive materials, for example, a metal such as platinum (Pt), tungsten (W), aluminum (Al), copper (Cu), tantalum (Ta), titanium (Ti), ruthenium (Ru), or molybdenum (Mo), a metal compound such as a metal nitride, for example, titanium nitride (TiN), or a metal alloy. The third conductive layer 180 may be formed by depositing a conductive material with a thickness that covers the process result in which the gate insulating layer 170 is formed and recessing the conductive material. This recess process may be performed by a dry or wet etching method using a gas or a chemical that can selectively remove conductive material.

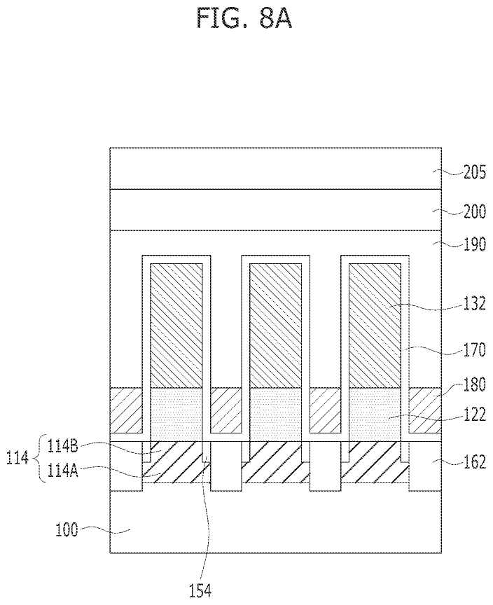

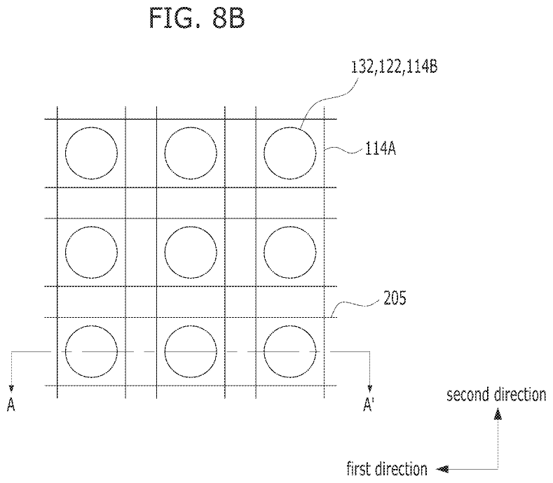

Referring to FIGS. 8A and 8B, a third insulating layer 190 covering the process result of FIG. 7 may be formed, and then, a second hard mask layer 200 and a third mask pattern 205 may be formed sequentially over the third insulating layer 190.

The third insulating layer 190 may include silicon oxide, silicon nitride, silicon oxynitride, or a combination thereof. The third insulating layer 190 may be formed by depositing an insulating material covering the process result of FIG. 7 and performing a planarization process to have a flat upper surface.

The second hard mask layer 200 may be a part that functions as an etch barrier when etching the third insulating layer 190 and the third conductive layer 180 and may include at least one of various materials such as silicon oxide, silicon nitride, polysilicon, carbon, or a combination thereof.

The third mask pattern 205 may include a photoresist and may have a line shape extending in the first direction to cover the stacked structures of the upper portion 114B of the first conductive pattern 114, the oxide semiconductor pattern 122, and the second conductive pattern 132, that are arranged in the first direction. To sufficiently cover the stacked structure in the second direction, the width of the third mask pattern 205 in the second direction may be greater than the width of the stacked structure in the second direction.

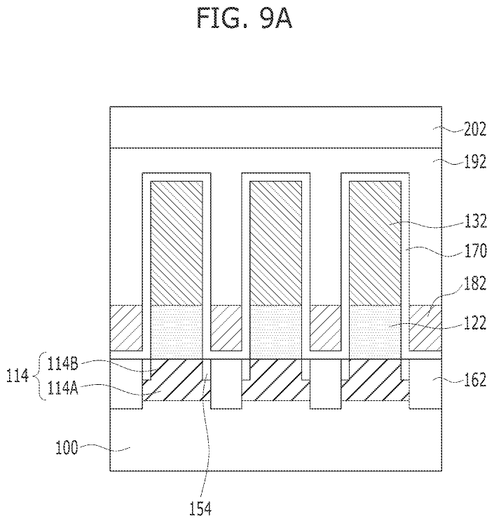

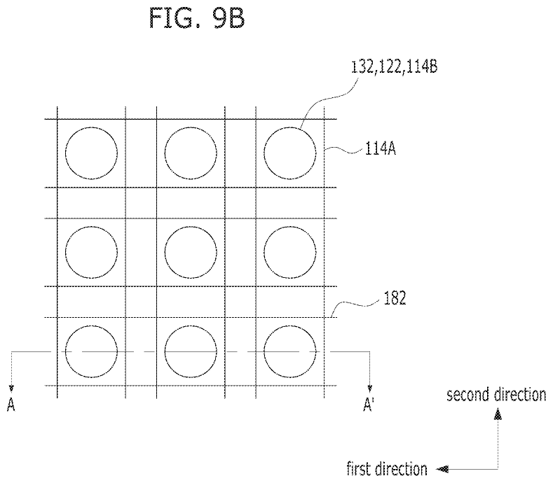

Referring to FIGS. 9A and 9B, the second hard mask layer 200, the third insulating layer 190, and the third conductive layer 180 may be etched using the third mask pattern 205 as an etch barrier to form a second hard mask pattern 202, an initial third insulating pattern 192, and a third conductive pattern 182. During this etching process, the third mask pattern 205 may be removed. Alternatively, the third mask pattern 205 may be removed through a separate removal process, such as an oxygen stripping process.

The third conductive pattern 182 may have a line shape extending in the first direction. The third conductive pattern 182 may correspond to a gate line and/or a word line. The width of the third conductive pattern 182 in the second direction may be greater than the width of the stacked structure of the upper portion 114B of the first conductive pattern 114, the oxide semiconductor pattern 122, and the second conductive pattern 132 in the second direction.

The initial third insulating pattern 192 and the second hard mask pattern 202 may cover the gate insulating layer 170 protruding above the third conductive pattern 182 and may have a line shape extending in the first direction in a plan view. Although not shown, a line-shaped space may be located between the initial third insulating patterns 192 and between the second hard mask patterns 202 in the second direction. After this etching process, an additional insulating material may be formed to fill this space.

Referring to FIG. 10, the second hard mask pattern 202 may be removed, and then, the initial third insulating pattern 192 and the gate insulating layer 170 may be recessed so that a portion of the sidewall and the top surface of the second conductive pattern 132 are exposed, thereby forming a third insulating pattern 194 and a gate insulating pattern 172.

A portion of the second conductive pattern 132 that protrudes above the third insulating pattern 194 and the gate insulating pattern 172 will be referred to as an upper portion UP of the second conductive pattern 132, and a remaining portion of the second conductive pattern 132 will be referred to as a lower portion LP of the second conductive pattern 132. As described above, the lower portion LP of the second conductive pattern 132 may correspond to a source electrode, and the upper portion UP of the second conductive pattern 132 may correspond to a lower electrode of a capacitor. The thickness of the upper portion UP of the second conductive pattern 132 may be greater than the thickness of the lower portion LP of the second conductive pattern 132. This may secure or improve the capacitance of the capacitor by increasing the thickness of the lower electrode of the capacitor.

The recess process may be performed using a dry or wet etching method using a gas or a chemical that can selectively remove only the insulating material. When the initial third insulating pattern 192 and the gate insulating layer 170 are formed of the same material, they may be recessed in a single step (at once) using the same etching gas or chemical. Alternatively, when the initial third insulating pattern 192 and the gate insulating layer 170 are formed of different materials, especially when they are formed of materials with different etch rates, the initial third insulating pattern 192 may be primarily recessed, and then, the gate insulating layer 170 exposed by the primary recess may be secondarily recessed to form the third insulating pattern 194 and the gate insulating pattern 172. The top surface of the third insulating pattern 194 and the top surface of the gate insulating pattern 172 formed through this recess process may be positioned at substantially the same height.

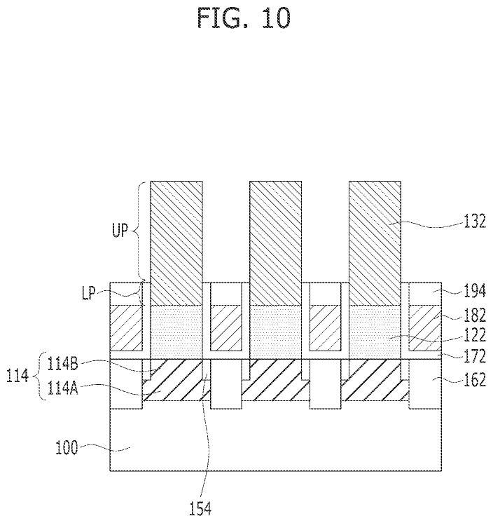

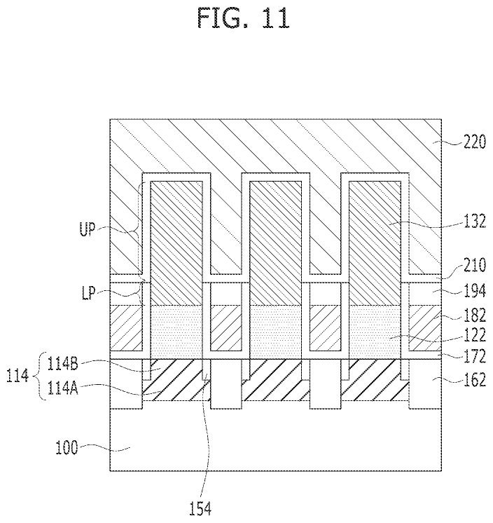

Referring to FIG. 11, a capacitor insulating layer 210 may be formed conformally along its lower profile over the process result of FIG. 10. Accordingly, the capacitor insulating layer 210 may be formed to cover the upper portion UP of the second conductive pattern 132, that is, the sidewall and the top surface of the lower electrode of the capacitor.

The capacitor insulating layer 210 may be formed using at least one of various deposition methods. The capacitor insulating layer 210 may include a high dielectric constant material with a higher dielectric constant than silicon oxide. The high dielectric constant material may include hafnium oxide (HfO₂), zirconium oxide (ZrO₂), aluminum oxide (Al₂O₃), titanium oxide (TiO₂), tantalum oxide (Ta₂O₅), niobium oxide (Nb₂O₅), strontium titanium oxide (SrTiO₃), or a combination thereof. The capacitor insulating layer 210 may include a material different from the gate insulating pattern 172, for example, a material having a higher dielectric constant than the gate insulating pattern 172. Alternatively, the capacitor insulating layer 210 may include the same material as the gate insulating pattern 172.

Subsequently, a fourth conductive layer 220 may be formed over the capacitor insulating layer 210.

The fourth conductive layer 220 may function as an upper electrode of a capacitor. The fourth conductive layer 220 may include at least one of various conductive materials, for example, a metal such as platinum (Pt), tungsten (W), aluminum (Al), copper (Cu), tantalum (Ta), titanium (Ti), ruthenium (Ru), or molybdenum (Mo), a metal compound such as a metal nitride, for example, titanium nitride (TiN), or a metal alloy. The fourth conductive layer 220 may be formed to a sufficient thickness so that it extends over the top surface of the second conductive pattern 132 while completely filling the space between the upper portions UP of the second conductive patterns 132. The fourth conductive layer 220 may be formed by depositing a conductive material and performing a planarization process to have a flat upper surface.

The semiconductor device such as that shown in FIG. 11 may be fabricated using the fabricating method described above.

Referring again to FIG. 11 together with FIG. 9B, the semiconductor device of the present embodiment may include the substrate 100, the lower portion 114A of the first conductive pattern 114 disposed over the substrate 100 and extending in the second direction, the stacked structure of the upper portion 114B of the first conductive pattern 114, the oxide semiconductor pattern 122, and the second conductive pattern 132 disposed over the lower portion 114A of the first conductive pattern 114 and having a pillar shape, the third conductive pattern 182 extending in the first direction while surrounding the sidewall of the oxide semiconductor pattern 122 with the gate insulating pattern 172 interposed therebetween, the third insulating pattern 194 covering the oxide semiconductor pattern 122 and filling the space between the lower portions LP of the second conductive patterns 132, the capacitor insulating layer 210 formed along the sidewall and the top surface of the upper portion UP of the second conductive pattern 132 protruding from the third insulating pattern 194, and the fourth conductive layer 220 covering the capacitor insulating layer 120.

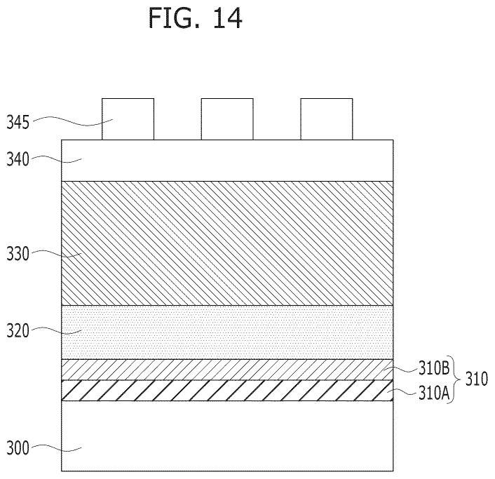

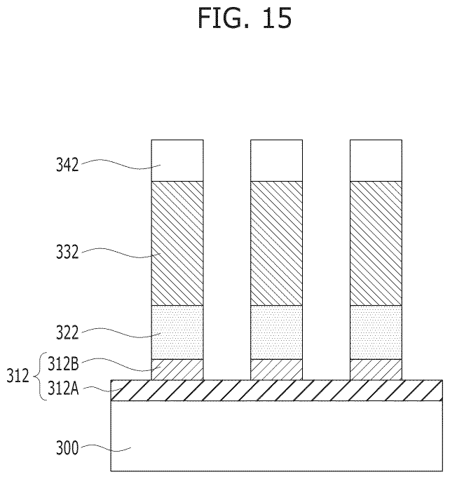

The lower portion 114A of the first conductive pattern 114 may be referred to as a bit line. The upper portion 114B of the first conductive pattern 114 may be referred to as a drain electrode, the oxide semiconductor pattern 122 may be referred to as an oxide semiconductor channel, the lower portion LP of the second conductive pattern 132 may be referred to as a source electrode, and the conductive pattern 182 may be referred to as a word line. One oxide semiconductor channel 122, one drain electrode 114B and one source electrode LP respectively connected to the bottom and top of the one oxide semiconductor channel 122, and the word line 182 surrounding the one oxide semiconductor channel 122 with the gate insulating pattern 172 therebetween may form one transistor. In the present embodiment, the word line 182 is shown to surround the entire sidewall of the oxide semiconductor channel 122 in a plan view, but the present disclosure is not limited thereto. In another embodiment, the word line 182 may face a portion of the sidewall of the oxide semiconductor channel 122 with the gate insulating pattern 172 therebetween in a plan view. Since the bit line 114A and the drain electrode 114B are formed as one integral element (one single piece), they may be formed of the same conductive metal oxide and there may be no interface between them. Here, the same conductive metal oxide may mean that the constituent elements are the same, and the content of the constituent elements may be different. For example, as in the embodiment of FIGS. 14 and 15 described later, the bit line 114A and the drain electrode 114B may include the same conductive metal oxide, but the metal content and/or oxygen content may be different from each other.

The upper portion UP of the second conductive pattern 132 may be referred to as a lower electrode of a capacitor, and the fourth conductive pattern 220 may be referred to as an upper electrode of the capacitor. One lower electrode UP and the upper electrode 220 surrounding the sidewall and the top surface of the one lower electrode UP with the capacitor insulating layer 210 interposed therebetween may form one capacitor. Because the source electrode LP and the lower electrode UP are formed as one piece, they may be formed of the same metal oxide and there may be no interface between them.

As a result, an 1T-1C semiconductor device including a transistor having a channel extending in the vertical direction and a capacitor connected to the transistor may be implemented.

A detailed description of components of the semiconductor device of the present embodiment has already been described in the above-described fabricating method and will therefore be omitted.

According to the semiconductor device and its fabricating method of the present embodiment, the following advantages may be obtained.

First, since the oxide semiconductor channel 122 extends in the vertical direction and the bit line 114A is buried under the oxide semiconductor channel 122, the area of the semiconductor device may be reduced.

In addition, since an oxide semiconductor material is used as a channel of a transistor, the resulting advantages, such as reduction of off-state current, may be secured.

In addition, process simplification may be possible. For example, the ion implantation process for forming wells, channels, source/drain regions, or the like, may be omitted, the bit line 114A and the drain electrode 114B may be formed integrally, and the source electrode LP and the lower electrode UP of a capacitor may be formed integrally.

In addition, by using a conductive metal oxide as the drain electrode 114B and the source electrode LP, the contact resistance may be reduced compared to a comparative example using a metal source electrode or a metal drain electrode. This may be because the formation of insulating metal oxide is suppressed at the interface between the metal source electrode and the oxide semiconductor channel or between the metal drain electrode and the oxide semiconductor channel. In addition, in the comparative example, the metal source electrode or the metal drain electrode may take away oxygen from the oxide semiconductor channel, causing an undesirable increase in oxygen vacancies in the oxide semiconductor channel and resulting deterioration of channel characteristics. In the present embodiment, this problem may be solved.

Furthermore, because the bit line 114A uses a conductive metal oxide such as a metallic oxide semiconductor instead of a highly doped semiconductor material, sheet resistance may be reduced.

As a result, the characteristics of the semiconductor device may be improved and the area of the semiconductor device may be reduced, while the fabricating process may be simplified.

In the present embodiment, a first case where the bit line 114A and the drain electrode 114B are formed of the same conductive metal oxide, and a second case where the source electrode LP and the lower electrode UP of a capacitor are formed of the same conductive metal oxide, have been described. However, one of the first and second cases may be possible. As an example, the bit line 114A and the drain electrode 114B may be formed as in the present embodiment, and a source electrode and a lower electrode of a capacitor may be formed separately. As another example, the source electrode LP and the lower electrode UP may be formed as in the present embodiment, and a bit line a drain electrode may be formed separately.

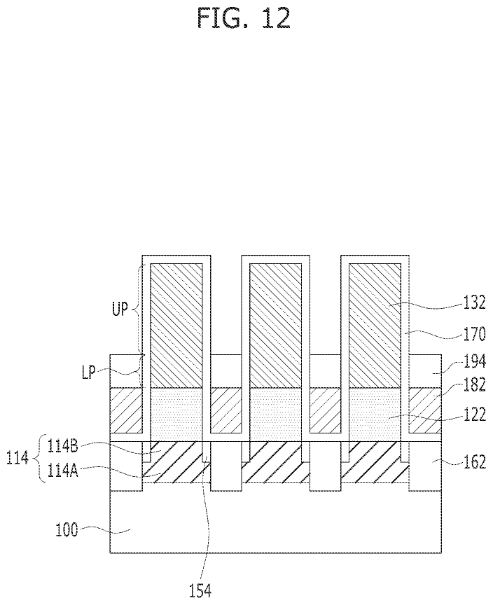

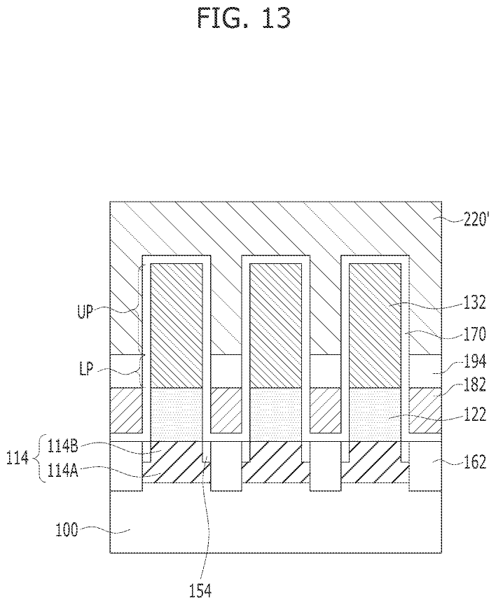

FIGS. 12 and 13 are simplified cross-sectional view schematics illustrating a semiconductor device according to another embodiment of the present disclosure, and a method for fabricating the same. The description will focus on differences from the above-described embodiment.

Referring to FIG. 12, after performing the process of FIGS. 9A and 9B described above, the second hard mask pattern 202 may be removed, and the initial third insulating pattern 192 may be recessed thereby forming the third insulating pattern 194 and the upper portion UP of the second conductive pattern 132 protrudes above the formed third insulating pattern 194. Unlike the process of FIGS. 10A and 10B described above, in this process, the gate insulating layer 170 may be maintained without being recessed.

The upper portion UP of the second conductive pattern 132 protruding above the third insulating pattern 194 may correspond to a lower electrode of a capacitor, and the lower portion LP of the second conductive pattern 132 may correspond to a source electrode.

The recess process may be performed using a dry or wet etching method using a gas or a chemical that can selectively remove only the initial third insulating pattern 192. To this end, the third insulating pattern 192 and the gate insulating layer 170 may be formed of materials having different etch rates. Furthermore, as will be described later with reference to FIG. 13, the gate insulating layer 170 may also function as a capacitor insulating layer, so it may include a high dielectric constant material to secure adequate capacitance. As an example, the third insulating pattern 192 may include a silicon-containing insulating material such as silicon oxide, silicon nitride, silicon oxynitride, or a combination thereof, and the gate insulating layer 170 may include a high dielectric constant material such as hafnium oxide (HfO₂), zirconium oxide (ZrO₂), aluminum oxide (Al₂O₃), titanium oxide (TiO₂), tantalum oxide (Ta₂O₅), niobium oxide (Nb₂O₅), strontium titanium oxide (SrTiO₃), or a combination thereof.

Referring to FIG. 13, a fourth conductive layer 220′ may be formed over the process result of FIG. 12.

The fourth conductive layer 220′ may function as an upper electrode of a capacitor. The gate insulating layer 170 between the fourth conductive layer 220′ and the second conductive pattern 132 may function as a capacitor insulating layer. On the other hand, the gate insulating layer 170 between the third conductive pattern 182 and the oxide semiconductor pattern 122 may perform its own function, that is, a function of a gate insulator.

According to the present embodiment, since the gate insulating layer 170 is also used as a capacitor insulating layer, a separate process for forming a capacitor insulating layer may be unnecessary. Therefore, process simplification may be possible.

FIGS. 14 and 15 are simplified cross-sectional view schematics illustrating a semiconductor device according to another embodiment of the present disclosure, and a method for fabricating the same. The description will focus on differences from the above-described embodiments.

Referring to FIG. 14, a first conductive layer 310, an oxide semiconductor layer 320, a second conductive layer 330, a first hard mask layer 340, and a first mask pattern 345 may be formed over a substrate 300. Except for the first conductive layer 310, the substrate 300, the oxide semiconductor layer 320, the second conductive layer 330, the first hard mask layer 340, and the first mask pattern 345 may correspond to the substrate 100, the oxide semiconductor layer 120, the second conductive layer 130, the first hard mask layer 140, and the first mask pattern 145 which are shown in FIGS. 1A and 1B, respectively.

The first conductive layer 310 may include a conductive metal oxide such as ITO, In₂O₃, or a metallic oxide semiconductor. In the present embodiment, the first conductive layer 310 may include a stacked structure of a lower first conductive layer 310A and an upper first conductive layer 310B. Through a patterning process described later, the lower first conductive layer 310A and the upper first conductive layer 310B may function as a bit line and a drain electrode, respectively.

The lower first conductive layer 310A and the upper first conductive layer 310B may include a conductive metal oxide. The content of a specific metal element in the lower first conductive layer 310A may be greater than that of the upper first conductive layer 310B. Here, when the lower first conductive layer 310A and the upper first conductive layer 310B include two or more metal elements, the specific metal element may refer to a metal element with the greatest bonding force with oxygen among the two or more metal elements. As an example, when the lower first conductive layer 310A and the upper first conductive layer 310B include ITO, the tin (Sn) content of the lower first conductive layer 310A may be greater than that of the upper first conductive layer 310B. The etch rate of a conductive metal oxide may decrease as the content of the specific metal element in the conductive metal oxide increases. For example, the etch rate of ITO may decrease as the tin content in the ITO increases. Therefore, the etch rate of the lower first conductive layer 310A may be smaller than the etch rate of the upper first conductive layer 310B. Accordingly, when etching the upper first conductive layer 310B, which is described later, it may be easier to stop the etching at the lower first conductive layer 310A.

Alternatively, the lower first conductive layer 310A and the upper first conductive layer 310B may include a conductive metal oxide, and the oxygen content of the lower first conductive layer 310A may be greater than the oxygen content of the upper first conductive layer 310B. As the oxygen content in a conductive metal oxide increases, the oxygen vacancies in the conductive metal oxide may decrease, so the porosity and the etch rate of the conductive metal oxide may decrease. Oxygen vacancies may refer to the absence of oxygen atoms within the crystal lattice of the metal oxide material. Thus, the porosity of the lower first conductive layer 310A may be smaller than the porosity of the upper first conductive layer 310B, and because of the lower porosity the etch rate of the lower first conductive layer 310A may be smaller than the etch rate of the upper first conductive layer 310B. Accordingly, when etching the upper first conductive layer 310B, which will be described later, it may be easier to stop the etching at the lower first conductive layer 310A.

The method of controlling the etch rate by adjusting the content of the specific metal element in the lower first conductive layer 310A and the upper first conductive layer 310B may be applied when each of the lower first conductive layer 310A and the upper first conductive layer 310B contains two or more metal elements. The method of controlling the etch rate by adjusting the oxygen content in the lower first conductive layer 310A and the upper first conductive layer 310B may be applied when each of the lower first conductive layer 310A and the upper first conductive layer 310B contains one metal element or two or more metal elements.

The lower first conductive layer 310A and the upper first conductive layer 310B may be deposited in-situ. The deposition may be performed by increasing the content of the specific metal, such as tin, when depositing the lower first conductive layer 310A, and lowering the content of the specific metal, such as tin, when depositing the upper first conductive layer 310B. As an example, when the lower first conductive layer 310A and the upper first conductive layer 310B are formed by depositing an ITO material by co-sputtering, the Sn content may be increased during forming the lower first conductive layer 310A, by increasing the power of the SnO₂ target compared to the In₂O₃ target, and the Sn content may be lowered during forming the upper first conductive layer 310B, by lowering the power of the SnO₂ target compared to the In₂O₃ target. Alternatively, as another example, when the lower first conductive layer 310A and the upper first conductive layer 310B are formed by depositing an ITO material using an ALD (Atomic Layer Deposition) method, the Sn content may be increased during the forming of the lower first conductive layer 310A, by increasing the number of the SnO₂ sub-cycles compared to the number of the In₂O₃ sub-cycles, and the Sn content may be lowered during the forming of the upper first conductive layer 310B, by lowering the number of the SnO₂ sub-cycles compared to the number of the In₂O₃ sub-cycles.

Alternatively, the deposition may be performed by reducing the flow rate of an oxygen-containing gas, such as O₂ gas, during the deposition of the upper first conductive layer 310B compared to the flow rate of the oxygen-containing gas, such as O₂ gas, during the deposition of the lower first conductive layer 310A.

Referring to FIG. 15, the first hard mask layer 340, the second conductive layer 330, the oxide semiconductor layer 320, and the first conductive layer 310 may be etched using the first mask pattern 345 as an etch barrier to form a first hard mask pattern 342, a second conductive pattern 332, an oxide semiconductor pattern 322, and an initial first conductive pattern 312.

Here, the initial first conductive pattern 312 may include an upper first conductive pattern 312B that is etched and an initial lower first conductive pattern 312A that is not etched. A stacked structure of the upper first conductive pattern 312B, the oxide semiconductor pattern 322, the second conductive pattern 332, and the first hard mask pattern 342 may have a pillar shape. The initial first lower conductive pattern 312A may maintain a flat plate shape. The upper first conductive pattern 312B may correspond to a drain electrode. The initial lower first conductive pattern 312A may be patterned into a line shape in a subsequent process and may function as a bit line.

According to the present embodiment, since the etch rate of the lower first conductive layer 310A is lower than the etch rate of the upper first conductive layer 310B, it may be easy for the etching to stop at the lower first conductive layer 310A during the etching process. In this case, since the lower first conductive layer 310A has a substantially uniform thickness, the distribution of the bit line thickness, that is, the distribution of the bit line resistance, may be improved.

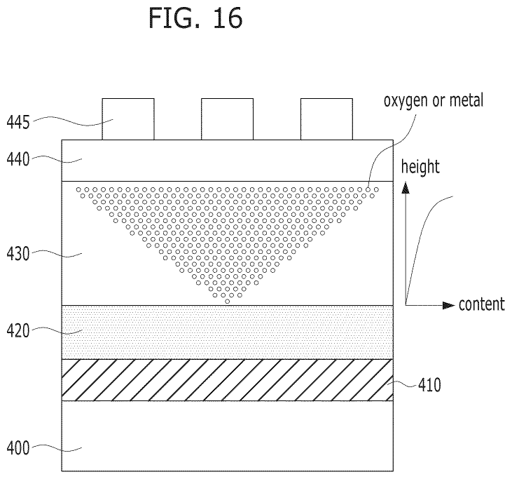

FIG. 16 is a simplified cross-sectional view schematic illustrating a semiconductor device according to another embodiment of the present disclosure, and a method for fabricating the same. The description will focus on differences from the above-described embodiments.

Referring to FIG. 16, a first conductive layer 410, an oxide semiconductor layer 420, a second conductive layer 430, a first hard mask layer 440, and a first mask pattern 445 may be formed over a substrate 400. The first conductive layer 410, the oxide semiconductor layer 420, the second conductive layer 430, the first hard mask layer 440, and the first mask pattern 445 may be formed sequentially over the substrate 400 according to the recited order. Except for the second conductive layer 430, the substrate 400, the first conductive layer 410, the oxide semiconductor layer 420, the first hard mask layer 440, and the first mask pattern 445 may correspond to the substrate 100, the first conductive layer 110, the oxide semiconductor layer 120, the first hard mask layer 140, and the first mask pattern 145 shown in FIGS. 1A and 1B, respectively.

The second conductive layer 430 may include a conductive metal oxide such as ITO, In₂O₃, or a metallic oxide semiconductor. In the present embodiment, the second conductive layer 430 may include a conductive metal oxide in which the content of a specific metal element and/or oxygen content increases from bottom to top. The content of the specific metal element or oxygen in the second conductive layer 430 may be indicated in a graph on the right side of the second conductive layer 430. As described above, as the content of a specific metal element or the oxygen content in a conductive metal oxide increases, the etch rate of the conductive metal oxide decreases. Therefore, in the process of etching the second conductive layer 430 to form a pillar-shaped second conductive pattern (not shown), the phenomenon in which the upper portion of the second conductive pattern is lost and has a bowing profile may be minimized and/or prevented. The sidewall of the second conductive pattern may have a vertical profile that is substantially perpendicular to the surface of the substrate 400.

When depositing the second conductive layer 430, a method in which the content of the specific metal element increases from bottom to top may be used. Alternatively, when depositing the second conductive layer 430, the flow rate of the oxygen-containing gas may increase from bottom to top.

The embodiments described above may be applicable to semiconductor devices including NMOS transistors, PMOS transistors, or CMOS transistors, and manufacturing methods thereof. For example, the embodiments described above may be applicable to at least one of various semiconductor devices, for example, non-volatile memory such as flash memory, resistive random-access memory (RRAM), phase-change random-access memory (PRAM), or magneto resistive random-access memory (MRAM), volatile memory such as dynamic random-access memory (DRAM) or static random-access memory (SRAM), non-memory such as logic circuit, or CIS (CMOS Image Sensor).

According to the above embodiments of the present disclosure, it is possible to provide a semiconductor device that improves its characteristics and reduces its area while simplifying the manufacturing process.

Although various embodiments have been described for illustrative purposes, it will be apparent to those skilled in the art that various changes and modifications may be made without departing from the spirit and scope of the present teachings as defined in the following claims. Furthermore, the embodiments may be combined to form additional embodiments.

What is claimed is:

1. A semiconductor device comprising:
a substrate;
a lower portion of a first conductive pattern disposed over the substrate and extending in a second direction;
a stacked structure disposed over the lower portion of the first conductive pattern and having a pillar shape, the stacked structure including an upper portion of the first conductive pattern, an oxide semiconductor channel, and a second conductive pattern; and
a word line extending in a first direction intersecting the second direction and facing at least a portion of a sidewall of the oxide semiconductor channel with a gate insulating layer therebetween,
wherein the first conductive pattern includes a first conductive metal oxide. and
the lower portion of the first conductive pattern corresponds to a bit line, and the upper portion of the first conductive pattern corresponds to a drain electrode.

2. The semiconductor device according to claim 1, wherein there is no interface between the lower portion of the first conductive pattern and the upper portion of the first conductive pattern.

3. The semiconductor device according to claim 1, wherein, in the first direction, a width of the lower portion of the first conductive pattern is greater than a width of the stacked structure.

4. The semiconductor device according to claim 1,
wherein the first conductive pattern includes two or more metal elements,
wherein a metal element among the two or more metal elements having a greatest bonding force with oxygen is referred to as a first metal element, and
wherein a content of the first metal element in the lower portion of the first conductive pattern is greater than a content of the first metal element in the upper portion of the first conductive pattern.

5. The semiconductor device according to claim 1, wherein an oxygen content of the lower portion of the first conductive pattern is greater than an oxygen content of the upper portion of the first conductive pattern.

6. The semiconductor device according to claim 1, wherein the first conductive metal oxide includes ITO, In₂O₃, or a metallic oxide semiconductor.

7. The semiconductor device according to claim 1, wherein the second conductive pattern includes a lower portion corresponding to the source electrode and an upper portion corresponding to a lower electrode of a capacitor.

8. The semiconductor device according to claim 7, wherein there is no interface between the lower portion of the second conductive pattern and the upper portion of the second conductive pattern.

9. The semiconductor device according to claim 7, wherein the second conductive pattern includes a second conductive metal oxide.

10. The semiconductor device according to claim 9,
wherein the second conductive pattern includes two or more metal elements,
wherein a metal element among the two or more metal elements having a greatest bonding force with oxygen is referred to as a first metal element, and
wherein a content of the first metal element in the second conductive pattern increases from bottom to top of the second conductive pattern.

11. The semiconductor device according to claim 9, wherein an oxygen content of the second conductive pattern increases from bottom to top.

12. The semiconductor device according to claim 9, wherein the second conductive metal oxide includes ITO, In₂O₃, or a metallic oxide semiconductor.

13. The semiconductor device according to claim 7, further comprising:
a capacitor insulating layer surrounding a sidewall and a top surface of the upper portion of the second conductive pattern; and
an upper electrode of the capacitor formed over the capacitor insulating layer.

14. The semiconductor device according to claim 13, wherein the gate insulating layer and the capacitor insulating layer include the same material.

15. A semiconductor device comprising:
a substrate;
a bit line disposed over the substrate and extending in a second direction;
a stacked structure disposed over the bit line and having a pillar shape, the stacked structure including a drain electrode, an oxide semiconductor channel, and a conductive pattern; and
a word line extending in a first direction intersecting the second direction and facing at least a portion of a sidewall of the oxide semiconductor channel with a gate insulating layer therebetween,
wherein the conductive pattern includes a conductive metal oxide, and
a lower portion of the conductive pattern corresponds to a source electrode, and an upper portion of the conductive pattern corresponds to a lower electrode of a capacitor.

16. The semiconductor device according to claim 15, wherein there is no interface between the lower portion of the conductive pattern and the upper portion of the conductive pattern.

17. The semiconductor device according to claim 15, wherein the conductive pattern includes two or more metal elements,
wherein a metal element among the two or more metal elements having a greatest bonding force with oxygen is referred to as a first metal element, and
wherein a content of the first metal element in the conductive pattern increases from bottom to top.

18. The semiconductor device according to claim 15, wherein an oxygen content of the conductive pattern increases from bottom to top.

19. The semiconductor device according to claim 15, wherein the conductive metal oxide includes ITO, In₂O₃, or a metallic oxide semiconductor.

20. The semiconductor device according to claim 15, further comprising:
a capacitor insulating layer surrounding a sidewall and a top surface of the upper portion of the conductive pattern; and
an upper electrode of the capacitor formed over the capacitor insulating layer.

21. The semiconductor device according to claim 20, wherein the gate insulating layer and the capacitor insulating layer include the same material.

22. A semiconductor device comprising:
a substrate;
a first conductive pattern disposed over the substrate and extending in a second direction, the first conductive pattern consisting of a line shape bottom part covering a top surface of the substrate, and a plurality of spaced apart pillar shape top parts rising over the bottom part in a vertical direction;
a plurality of stacked structures, each stacked structure disposed over a corresponding one of the pilar shape top parts of the first conductive pattern and having a pillar shape, each stacked structure including an oxide semiconductor channel, and a second conductive pattern sequentially stacked; and
a word line extending in a first direction intersecting the second direction and facing at least a portion of a sidewall of the oxide semiconductor channel with a gate insulating layer therebetween.

23. The semiconductor device according to claim 22, wherein there is no interface between the line shape bottom part of the first conductive pattern and the pillar shape top parts of the first conductive pattern.
